(19) United States
(12) Patent Application Publication
(10) Pub. No.: US 2017/0053914 A1
(43) Pub. Date: Feb. 23, 2017

(54) SEMICONDUCTOR DEVICE AND FABRICATION METHOD THEREFOR

(71) Applicant: FUJITSU LIMITED, Kawasaki-shi (JP)

(72) Inventors: Hiroko TASHIRO, Ashigarakami (JP); Takeshi ISHITSUKA, Isehara (JP)

(73) Assignee: FUJITSU LIMITED, Kawasaki-shi (JP)

(21) Appl. No.: 15/193,842

(22) Filed: Jun. 27, 2016

(30) Foreign Application Priority Data
Aug. 19, 2015 (JP) 2015-162113

(51) Int. Cl. H01L 27/092; H01L 21/8238; H01L 21/768; H01L 29/78; H01L 23/535

(52) U.S. Cl. CPC H01L 27/0922; H01L 29/7849; H01L 23/535; H01L 21/76895; H01L 21/823807; H01L 21/823871

(57) ABSTRACT

A semiconductor device includes a semiconductor substrate, a stress generation source that is provided on the semiconductor substrate and generates stress in the semiconductor substrate, and a first field-effect transistor and a second field-effect transistor provided on the semiconductor substrate. The first field-effect transistor and the semiconductor substrate are disposed such that channel directions from a source toward a drain are different from each other in response to positions with respect to the stress generation source.

### CROSS-REFERENCE TO RELATED APPLICATION

This application is based upon and claims the benefit of priority of the prior Japanese Patent Application No. 2015-162113, filed on Aug. 19, 2015, the entire contents of which are incorporated herein by reference.

### FIELD

The embodiments discussed herein are related to a semiconductor device and a fabrication method for a semiconductor device.

### BACKGROUND

In recent years, attention is paid to a technology that a through via such as, for example, a TSV (Through Silicon Via) is provided and three-dimensionally mounted on a semiconductor substrate such as, for example, a silicon substrate.

### SUMMARY

According to an aspect of the embodiment, a semiconductor device includes a semiconductor substrate, a stress generation source that is provided on the semiconductor substrate and generates stress in the semiconductor substrate, and a first field-effect transistor and a second field-effect transistor provided on the semiconductor substrate, wherein the first field-effect transistor and the semiconductor substrate are disposed such that channel directions from a source toward a drain are different from each other in response to positions with respect to the stress generation source.

According to an aspect of the embodiment, a fabrication method for a semiconductor device includes providing, on the semiconductor substrate, a stress generation source that generates stress in a semiconductor substrate, and providing a first field-effect transistor and a second field-effect transistor on the semiconductor substrate, wherein, at the providing the first field-effect transistor and the second field-effect transistor, the first field-effect transistor and the second field-effect transistor are disposed such that channel directions from a source toward a drain are different from each other in response to a position of the stress generation source.

The object and advantages of the invention will be realized and attained by means of the elements and combinations particularly pointed out in the claims. It is to be understood that both the foregoing general description and the following detailed description are exemplary and explanatory and are not restrictive of the invention.

### BRIEF DESCRIPTION OF DRAWINGS

FIGS. 1A to 2B are schematic top plan views depicting a configuration of a semiconductor device according to an embodiment;

FIG. 3A is a view illustrating a result when disposition dependency of a Vg-Id characteristic of an NMOSFET is analyzed, and FIG. 3B is a view illustrating a result when disposition dependency of a Vg-Id characteristic of a PMOSFET is analyzed;

FIG. 4 is a schematic top plan view depicting an example of disposition of NMOSFETs and PMOSFETs in a region over which stress generated by a TSV of the semiconductor device according to the embodiment extends and another region over which the stress does not extend;

FIG. 5 is a view illustrating a result when distance dependency between a drain current value and the TSV in the NMOS is analyzed;

FIG. 6A is a schematic top plan view depicting a placeable region of a conventional MOSFET, and FIG. 6B is a schematic top plan view depicting a placeable region of a MOSFET in the semiconductor device of the present embodiment;

FIG. 7A is a schematic view depicting disposition of an NMOSFET and a PMOSFET that configure a CMOS inverter of a comparative example, FIG. 7B is a view depicting a circuit configuration of the CMOS inverter of the comparative example, and FIGS. 7C and 7D are views illustrating results when an influence on an inverter characteristic (output current Iₒᵤₜ and output voltage Vₒᵤₜ) caused by stress generated by the TSV is analyzed by simulation in the comparative example;

FIG. 8A is a schematic view depicting disposition of an NMOSFET and a PMOSFET that configure a CMOS inverter of the embodiment described above, FIG. 8B is a view depicting a circuit configuration of the CMOS inverter of the embodiment, and FIGS. 8C and 8D are views illustrating results when an influence on an inverter characteristic (output current Iₒᵤₜ and output voltage Vₒᵤₜ) caused by stress generated by the TSV is analyzed by simulation in the embodiment described above;

FIG. 9 is a schematic top plan view depicting disposition of an NMOSFET and a PMOSFET that configure a general CMOS inverter; and

FIG. 10 is a flow chart illustrating an adjustment method (adjustment method for a gate angle) of a channel direction of the NMOSFET or the PMOSFET that configures the CMOS inverter at a design stage of the CMOS inverter.

### DESCRIPTION OF EMBODIMENTS

If through vias are provided on a semiconductor substrate as described above, then stress is generated around the through vias. It is to be noted that, also where bumps are provided on the semiconductor substrate, the stress is generated around the bumps.

Therefore, if a plurality of field-effect transistors are disposed on a semiconductor substrate such that channel directions coincide with each other, then a transistor characteristic is sometimes degraded in a region on which stress generated by a stress generation source such as, for example, a through via or a bump has an influence. In this case, while it seems a recommendable idea to dispose all of field-effect transistors in a region on which stress generated by the stress generation source does not have an influence, in this case, this makes it difficult to promote increase of the density and enhancement of high integration.

Therefore, it is desirable to suppress degradation of a transistor characteristic depending upon a position with respect to a stress generation source.

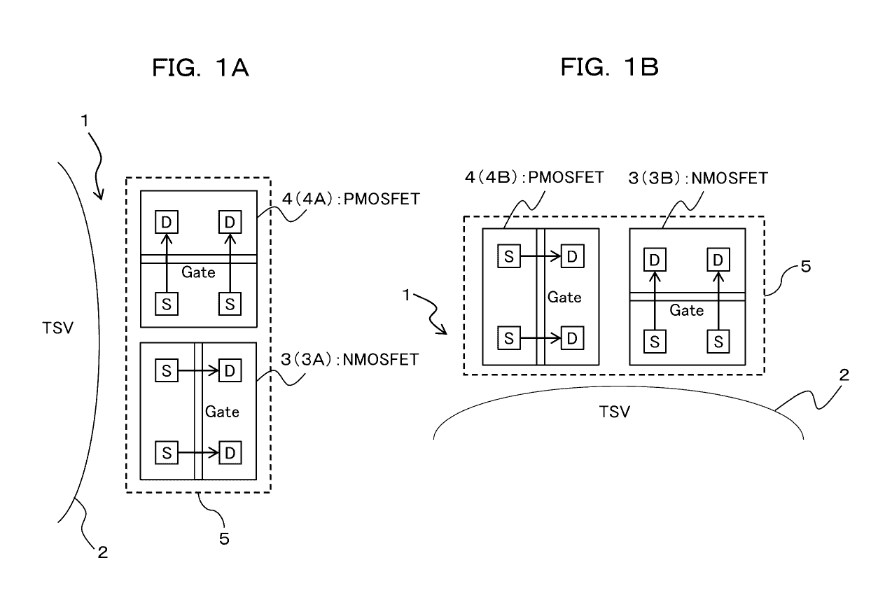

In the following, a semiconductor device and a fabrication method for a semiconductor device according to an embodiment are described with reference to FIGS. 1A to 10.

As depicted in FIGS. 1A and 1B, the semiconductor device according to the present embodiment includes a silicon substrate 1, a TSV 2 that is provided on the silicon substrate land generates stress in the silicon substrate 1, an N-channel MOSFET (Metal-oxide-semiconductor field-effect transistor; hereinafter referred to as NMOSFET) 3 and a P-channel MOSFET (hereinafter referred to as PMOSFET) 4 provided on the silicon substrate 1.

It is to be noted that FIG. 1A depicts disposition where the NMOSFET 3 and the PMOSFET 4 are provided at the right side of the TSV 2 as viewed from above, and FIG. 1B depicts disposition where the NMOSFET 3 and the PMOSFET 4 are provided at the upper side of the TSV 2 as viewed from above.

Further, the silicon substrate 1 is referred to sometimes as semiconductor substrate. Further, since the TSV 2 is a via extending through the silicon substrate 1, the TSV 2 is referred to sometimes as through via. Further, since the TSV 2 is configured from a metal material such as, for example, copper and has a thermal expansion coefficient different from that of silicon that is a material of the silicon substrate 1, and generates stress in the silicon substrate 1, the TSV 2 is referred to sometimes as stress generation source or member having a thermal expansion coefficient different from that of silicon. Further, the N-channel MOSFET 3 is referred to sometimes as first field-effect transistor or N-channel field-effect transistor. Further, the P-channel MOSFET 4 is referred to sometimes as second field-effect transistor or P-channel field-effect transistor.

Here, the TSV 2 is used for implementing three-dimensional mounting, and a plurality of TSVs 2 are provided on the silicon substrate 1. Further, a plurality of NMOSFETs 3 and a plurality of PMOSFETs 4 are provided on the silicon substrate 1 and configure a MOSFET circuit.

In the present embodiment, the NMOSFET 3 and the PMOSFET 4 are positioned in a region over which stress generated by the TSV 2 extends and are disposed such that channel directions (indicated by arrow marks in FIGS. 1A and 1B) from the source S to the drain D are different from each other. In particular, the NMOSFET 3 and the PMOSFET 4 are disposed such that the channel directions are cross each other.

Here, a positional relationship with the TSV 2 and an influence on a current value in the channel direction are different between the NMOSFET 3 and the PMOSFET 4. This is because the mechanism of movement of a carrier is different depending upon whether the carrier is an electron or a hole.

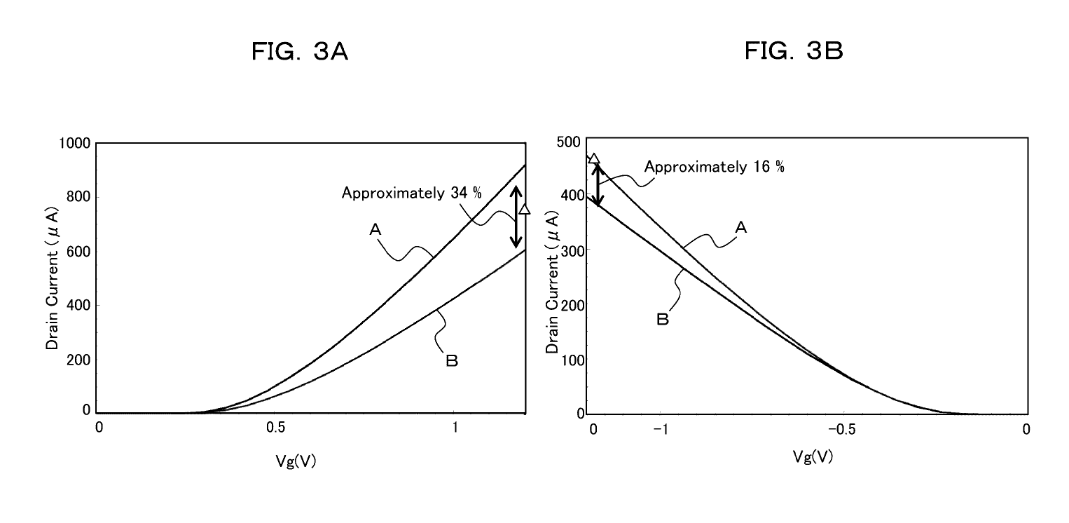

First, FIG. 3A depicts a result when a disposition dependency of a Vg-Id characteristic of the NMOSFET 3 provided on the (100) Si substrate 1 is analyzed.

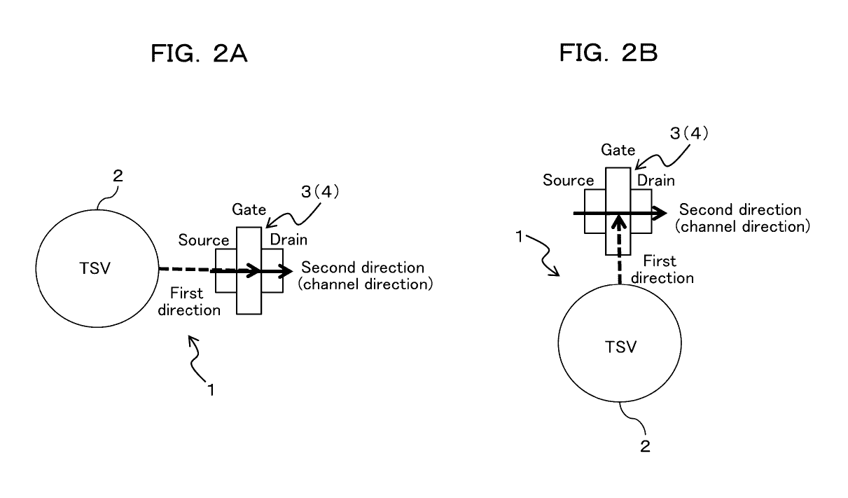

Here, in FIG. 3A, a solid line A indicates a Vg-Id characteristic where the NMOSFET 3 is disposed such that, when tensile stress is generated around the TSV 2 by a change of the temperature from high to low, for example, in a fabrication process, namely, when tensile stress is generated along a direction (first direction) from the center of the TSV 2 toward the center of the channel of the NMOSFET 3, the channel direction (second direction) and the direction (first direction) from the center of the TSV 2 toward the center of the channel of the NMOSFET 3 coincide with each other (first direction=second direction; refer to FIG. 2A).

Meanwhile, in FIG. 3A, a solid line B indicates a Vg-Id characteristic where the NMOSFET 3 is disposed such that, when tensile stress is generated along the direction (first direction) from the center of the TSV 2 toward the center of the channel of the NMOSFET 3, the channel direction (second direction) and the direction (first direction) from the center of the TSV 2 toward the center of the channel of the NMOSFET 3 are orthogonal to each other [first direction⊥(up tack) second direction; refer to FIG. 2B].

It is to be noted that, in this analysis, Vd=1.2 V, and the distance from a side face of the TSV 2 to the center of the channel of the NMOSFET 3 and the size (gate width) W in the depthwise direction of the NMOSFET 3 are set to approximately 2 μm and approximately 1 μm, respectively. Further, a maximum current value of the NMOSFET 3 when it is not acted upon by stress (namely, of the NMOSFET 3 provided in a region over which stress generated by the TSV 2 does not extend) is plotted with a triangular mark.

As depicted in FIG. 3A, in the case of the NMOSFET 3, the current value can be set highest by setting the first direction=second direction. Further, in the case of the NMOSFET 3, by setting the first direction=second direction, the maximum current value can be increased by approximately 34% in comparison with that in the case of the first direction⊥(up tack) second direction. Further, in the case of the NMOSFET 3, by setting the first direction=second direction, the current value can be increased in comparison also with that in the case where stress does not act. Further, in the case of the NMOSFET 3, if the first direction⊥(up tack) second direction is satisfied, then the current value decreases in comparison with that in the case where stress does not act.

Therefore, where tensile stress is generated along the direction (first direction) from the center of the TSV 2 toward the center of the channel of the NMOSFET 3 as depicted in FIG. 2A, the NMOSFET 3 positioned in the region over which the stress generated by the TSV 2 extends is disposed such that the channel direction (second direction) and the direction (first direction) from the center of the TSV 2 toward the center of the channel of the NMOSFET 3 coincide with each other. In particular, the NMOSFET 3 positioned in the region over which stress generated by the TSV 2 extends is disposed such that, when tensile stress is generated along the first direction, the first direction and the second direction coincide with each other or are opposite to each other.

Where the NMOSFET 3 is disposed in such a manner as described above, if attention is paid to stress in the channel direction, then the stress acts as tensile stress, namely, the tensile stress acts on the channel, and the mobility of electrons increases by the tensile stress. Therefore, by disposing the NMOSFET 3 in such a manner as described above, decrease or variability of the current value of the NMOSFET 3 by an influence of the stress generated by the TSV 2 can be suppressed and degradation of a characteristic of the NMOSFET 3 can be suppressed. In this case, the NMOSFET 3 is disposed such that the tensile stress acts on the channel.

FIG. 3B depicts a result when the disposition dependency of a Vg-Id characteristic of the PMOSFET 4 provided on the (100) Si substrate 1 is analyzed.

Here, in FIG. 3B, a solid line A indicates a Vg-Id characteristic where the PMOSFET 4 is disposed such that, when tensile stress is generated along the direction (first direction) from the center of the TSV 2 toward the center of the channel of the PMOSFET 4, the channel direction (second direction) and the direction (first direction) from the center of the TSV 2 toward the center of the channel of the PMOSFET 4 are orthogonal to each other [first direction⊥(up tack) second direction].

Further, in FIG. 3B, a solid line B indicates a Vg-Id characteristic where the PMOSFET 4 is disposed such that, when tensile stress is generated along the direction (first direction) from the center of the TSV 2 toward the center of the channel of the PMOSFET 4, the channel direction (second direction) and the direction (first direction) from the center of the TSV 2 toward the center of the channel of the PMOSFET 4 coincide with each other (first direction=second direction).

It is to be noted that, in this analysis, Vd is set to Vd=−1.2 V, and the distance from a side face of the TSV 2 to the center of the channel of the PMOSFET 4 and the size (gate width) W of the PMOSFET 4 in the depthwise direction are set to approximately 2 μm and approximately 1 μm, respectively. Further, the maximum current value of the PMOSFET 4 when stress does not act (namely, of the PMOSFET 4 provided in a region over which stress generated by the TSV 2 does not extend) is plotted by a triangular mark. Further, while the maximum current value is different between the NMOSFET 3 and the PMOSFET 4 in the result of the analysis in FIGS. 3A and 3B, by adjusting some other design parameter, for example, by adjusting the depth size W of the transistor, the maximum current values of the NMOSFET 3 and the PMOSFET 4 can be made so as to coincide with each other.

As depicted in FIG. 3B, in the case of the PMOSFET 4, the current value can be set highest by setting the first direction⊥(up tack) second direction. Further, in the case of the PMOSFET 4, by setting the first direction⊥(up tack) second direction, the maximum current value can be increased by approximately 16% in comparison with that of the case of the first direction=second direction. Further, in the case of the PMOSFET 4, if the first direction=second direction, then the current value decreases in comparison with that in the case where stress does not act. It is to be noted here that, while the maximum current value of the PMOSFET 4 where stress does not act substantially coincides with the current maximum value of the PMOSFET 4 in the case of the first direction⊥(up tack) second direction, if some design parameter is changed, then, by setting the first direction⊥(up tack) second direction, the current value can be increased in comparison also with that in the case where the stress does not act.

Therefore, if tensile stress is generated along the direction (first direction) from the center of the TSV 2 toward the center of the channel of the PMOSFET 4 as depicted in FIG. 2B, the PMOSFET 4 positioned in the region over which stress generated by the TSV 2 extends is disposed such that the channel direction (second direction) and the direction (first direction) from the center of the TSV 2 toward the center of the channel of the PMOSFET 4 are orthogonal to each other. In particular, when tensile stress is generated along the first direction, the PMOSFET 4 positioned in the region over which stress generated by the TSV 2 extends is disposed such that the first direction and the second direction are directed perpendicularly to each other.

Where the PMOSFET 4 is disposed in such a manner as described above, if attention is paid to the stress in the channel direction, then the stress acts as compressive stress, namely, the compressive stress acts on the channel, and the mobility of holes is increased by the compressive stress. Therefore, by disposing the PMOSFET 4 in such a manner as described above, it is possible to suppress decrease or variability of the current value of the PMOSFET 4 caused by an influence of stress generated by the TSV 2 and suppress degradation of a characteristic of the PMOSFET 4. In this case, the PMOSFET 4 is disposed such that compressive stress acts on the channel.

It is to be noted that the direction from the center of the TSV 2 toward the center of the channel of the NMOSFET 3 or the PMOSFET 4 is a direction in which a linear line that couples the center of the TSV 2 and the center of the channel of the NMOSFET 3 or the PMOSFET 4 with each other by the shortest distance extends, and is a direction from the surface of the silicon substrate 1 with which the side face at the side nearest to the NMOSFET 3 or the PMOSFET 4 of the TSV 2 contacts toward the surface of the silicon substrate 1 on which the center of the channel of the NMOSFET 3 or the PMOSFET 4 is positioned.

In this manner, the NMOSFET 3 and the PMOSFET 4 are disposed such that the channel direction differs in response to the position with respect to the TSV 2.

Such disposition as described above is adopted by the following reason.

A great number of TSVs are used in order to implement three-dimensional mounting. If the TSVs exist on a silicon substrate, then stress is generated locally around the TSVs and a stress distribution appears in the silicon substrate.

If such a TSV that generates stress as described above exists around a MOSFET circuit provided on the silicon substrate, then a transistor characteristic such as, for example, a current characteristic, of a transistor is degraded.

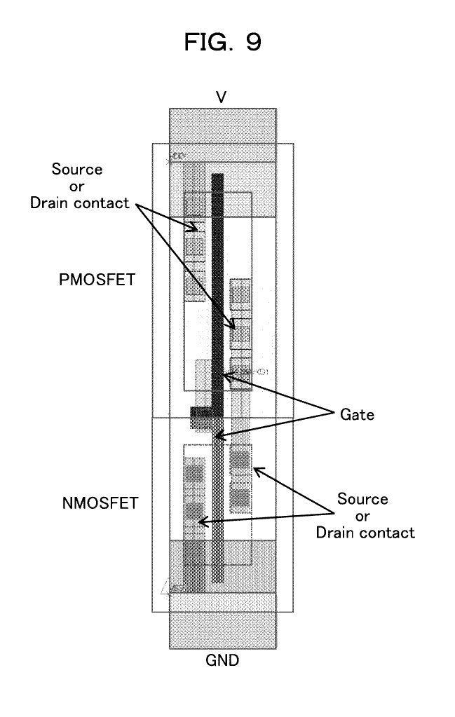

For example, if NMOSFETs and PMOSFETs are disposed on the overall face of the silicon substrate such that channel directions are arranged in parallel to each other (for example, refer to FIG. 9), then in a region that is influenced by stress generated by a TSV, decrease or variability of a current value of a transistor sometimes occurs, by which a transistor characteristic is degraded. Especially, in the progress of downsizing of a package size or miniaturization of transistors, the decrease or variability of a current value of transistors causes variability or degradation of a characteristic of transistors or a circuit in which transistors are used.

In this case, while it seems recommendable to dispose all of NMOSFETs and PMOSFETs in a region that is not influenced by stress generated by the TSV, this makes it difficult to progress promotion of the density and enhancement of high integration.

Therefore, the NMOSFET 3 and the PMOSFET 4 are disposed as described above in order to suppress degradation of a transistor characteristic depending upon a position with respect to the TSV 2.

Especially, even if the NMOSFET 3 and the PMOSFET 4 are disposed in the region over which stress generated by the TSV 2 extends, occurrence of decrease or variability of a current value of the transistors caused by an influence of the stress generated by the TSV 2 can be suppressed and degradation of a transistor characteristic can be suppressed.

In this manner, since degradation of a transistor characteristic can be suppressed, the NMOSFET 3 and the PMOSFET 4 can be disposed also in the region over which the stress generated by the TSV 2 extends, namely, the NMOSFET 3 and the PMOSFET 4 can be disposed very near to the TSV 2, and increase of the density and increase of the degree of integration can be achieved by disposing the NMOSFET 3 and the PMOSFET 4 in a high density.

Incidentally, the embodiment is described above taking, as an example, the case where the NMOSFET 3 and the PMOSFET 4 positioned in the region over which the stress generated by the TSV 2 extends are disposed such that the channel directions are different from each other, the present technology is not limited to this. For example, the first field-effect transistor and the second field-effect transistor may be disposed such that the channel directions are different from each other, namely, the channel directions are cross each other, in accordance with the positions with respect to the TSV (stress generation source).

For example, one NMOSFET 3A (3) and a different NMOSFET 3B (3) positioned in a region over which stress generated by the TSV 2 extends may be disposed such that the channel directions are different from each other (for example, refer to FIGS. 1A and 1B). It is to be noted that the one NMOSFET 3A is hereinafter referred to sometimes as first field-effect transistor or first N-channel field-effect transistor. Further, the different NMOSFET 3B is hereinafter referred to sometimes as second field-effect transistor or second N-channel field-effect transistor.

In this case, where tensile stress is generated along the direction (first direction) from the center of the TSV 2 toward the center of the channel of the one NMOSFET 3A, the one NMOSFET 3A positioned in the region over which the stress generated by the TSV 2 extends may be disposed such that the channel direction (second direction) and the direction (first direction) from the center of the TSV 2 toward the center of the channel of the one NMOSFET 3A coincide with each other. Further, where tensile stress is generated along the direction (first direction) from the center of the TSV 2 toward the center of the channel of the different NMOSFET 3B, the different NMOSFET 3B positioned in the region over which the stress generated by the TSV 2 extends may be disposed such that the channel direction (second direction) and the direction (first direction) from the center of the TSV 2 toward the center of the channel of the different NMOSFET 3B coincide with each other.

Further, for example, one PMOSFET 4A (4) and a different PMOSFET 4B (4) positioned in a region over which stress generated by the TSV 2 extends may be disposed such that the channel directions are different from each other (for example, refer to FIGS. 1A and 1B). It is to be noted that the one PMOSFET 4A is hereinafter referred to sometimes as first field-effect transistor or first P-channel field-effect transistor. Further, the different PMOSFET 4B is hereinafter referred to sometimes as second field-effect transistor or second P-channel field-effect transistor.

In this case, where tensile stress is generated along the direction (first direction) from the center of the TSV 2 toward the center of the channel of the one PMOSFET 4A, the one PMOSFET 4A positioned in the region over which the stress generated by the TSV 2 extends may be disposed such that the channel direction (second direction) and the direction (first direction) from the center of the TSV 2 toward the center of the channel of the one PMOSFET 4A are orthogonal to each other. Further, where tensile stress is generated along the direction (first direction) from the center of the TSV 2 toward the center of the channel of the different PMOSFET 4B, the different PMOSFET 4B positioned in the region over which the stress generated by the TSV 2 extends may be disposed such that the channel direction (second direction) and the direction (first direction) from the center of the TSV 2 toward the center of the channel of the different PMOSFET 4B are orthogonal to each other.

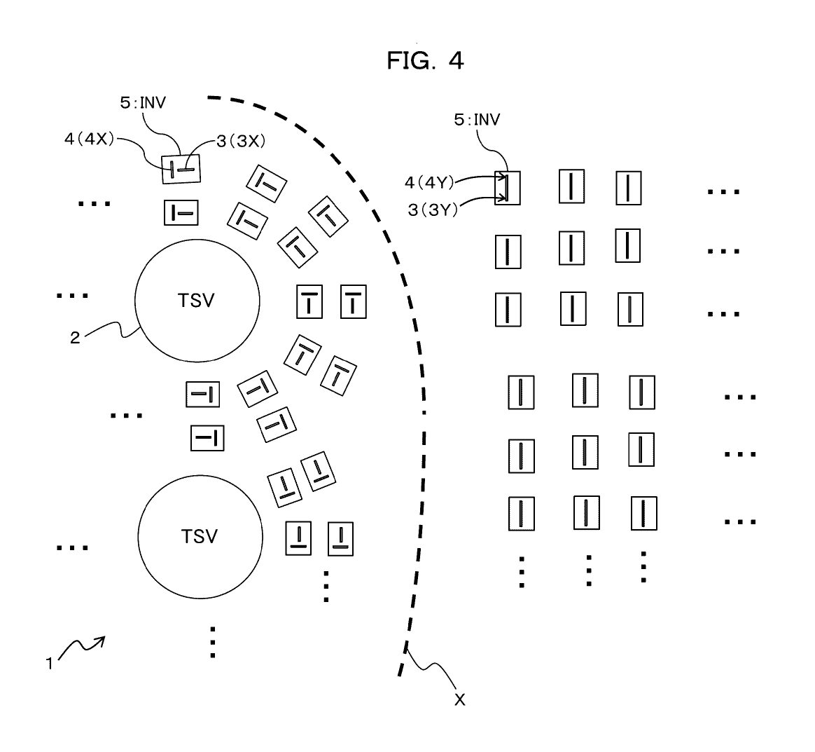

Further, one NMOSFET 3X (3) positioned in the region over which stress generated by the TSV 2 extends (for example, a region at the left side of a broken line indicated by reference character X in FIG. 4) and a different NMOSFET 3Y (3) positioned in the region over which the stress generated by the TSV 2 does not extend (for example, a region at the right side of the broken line indicated by reference character X in FIG. 4) may be disposed such that the channel directions are different from each other, namely, the channel directions are cross each other. It is to be noted that the one NMOSFET 3X is hereinafter referred to sometimes as first field-effect transistor or first N-channel field-effect transistor. Further, the different NMOSFET 3Y is hereinafter referred to sometimes as second field-effect transistor or second N-channel field-effect transistor. It is to be noted that, in order to facilitate recognition of the positional relationship in FIG. 4, only the gate of the NMOSFET 3 and PMOSFET 4 is indicated by a solid line, and a direction orthogonal to the gate is the channel direction. Further, FIG. 4 illustrates, as an example, a case in which a plurality of CMOS inverters (INVs) 5 configured by coupling the NMOSFET 3 and the PMOSFET 4 with each other are provided.

In this case, where tensile stress is generated along the direction (first direction) from the center of the TSV 2 toward the center of the channel of the one NMOSFET 3X, the one NMOSFET 3X positioned in the region over which the stress generated by the TSV 2 extends may be disposed such that the channel direction (second direction) and the direction (first direction) from the center of the TSV 2 toward the center of the channel of the one NMOSFET 3X coincide with each other (for example, refer to FIG. 4).

Further, for example, one PMOSFET 4X (4) positioned in the region over which the stress generated by the TSV 2 extends (for example, a region at the left side of the broken line indicated by reference character X in FIG. 4) and a different PMOSFET 4Y (4) positioned in the region over which the stress generated by the TSV 2 does not extend (for example, a region at the right side of the broken line indicated by reference character X in FIG. 4) may be disposed such that the channel directions are different from each other, namely, the channel directions are cross each other (for example, refer to FIG. 4). It is to be noted that the one PMOSFET 4X is hereinafter referred to sometimes as first field-effect transistor or first P-channel field-effect transistor. Further, the different PMOSFET 4Y is hereinafter referred to sometimes as second field-effect transistor or second P-channel field-effect transistor.

In this case, where tensile stress is generated along the direction (first direction) from the center of the TSV 2 toward the center of the channel of the one PMOSFET 4X, the one PMOSFET 4X positioned in the region over which stress generated by the TSV 2 extends may be disposed such that the channel direction (second direction) and the direction (first direction) from the center of the TSV 2 toward the center of the channel of the one PMOSFET 4X are orthogonal to each other (for example, refer to FIG. 4).

Further, for example, as in the embodiment described above, the NMOSFET 3X (3) and the PMOSFET 4X (4) positioned in the region over which the stress generated by the TSV 2 extends (for example, a region at the left side of the broken line indicated by reference character X in FIG. 4) may be disposed such that the channel directions are different from each other (namely, the channel directions cross with each other), and the different NMOSFET 3Y (3) and the different PMOSFET 4Y (4) positioned in the region over which the stress generated by the TSV 2 does not extend (for example, a region at the right side of the broken line indicated by reference character X in FIG. 4) may be disposed such that the channel directions are parallel to each other (for example, refer to FIG. 4). It is to be noted that the different NMOSFET 3Y is hereinafter referred to sometimes as different N-channel field-effect transistor. Further, the different PMOSFET 4Y is hereinafter referred to sometimes as different P-channel field-effect transistor.

Incidentally, while, in the embodiment described above, in the region over which the stress generated by the TSV 2 extends, the NMOSFET 3 is disposed such that the first direction and the second direction are same as or opposite to each other and the PMOSFET 4 is disposed such that the first direction and the second direction are orthogonal (perpendicular) to each other and the NMOSFET 3 and the PMOSFET 4 are disposed such that the channel directions of the NMOSFET 3 and the PMOSFET 4 are rotated by 90 degrees, the present technology is not limited to this.

For example, where a plurality of NMOSFETs 3 are provided in the region over which the stress generated by the TSV 2 extends, the plurality of NMOSFETs 3 may be disposed in a state in which a relationship between the channel direction (second direction) and the direction (first direction) from the center of the TSV 2 toward the center of the channel of the NMOSFET 3 is adjusted such that the maximum current values of the plurality of NMOSFETs 3 may remain within a permissible range.

In this case, one NMOSFET 3 and a different NMOSFET 3 positioned in the region over which the stress generated by the TSV 2 extends are disposed such that the channel directions are different from each other. Further, the maximum current values of the one NMOSFET 3 and the different NMOSFET 3 are within a permissible range. It is to be noted that the one NMOSFET 3 is hereinafter referred to sometimes as first field-effect transistor or first N-channel field-effect transistor. Further, the different NMOSFET 3 is hereinafter referred to sometimes as second field-effect transistor or second N-channel field-effect transistor.

Here, where tensile stress is generated along the first direction, if the NMOSFET 3 is disposed such that the first direction and the second direction are directed in the same directions as each other or in the opposite directions to each other, then the maximum current value can be maximized. Further, if the relationship between the first direction and the second direction of the NMOSFET 3 (namely, the angle of the channel direction of the NMOSFET 3 with respect to the direction from the center of the TSV 2 toward the center of the channel of the NMOSFET 3; a gate angle of the NMOSFET 3) is adjusted from the disposition in which the first direction and the second direction are directed in the same direction or in the opposite directions to each other toward the disposition in which the first direction and the second direction are orthogonal to each other, then the maximum current value can be decreased.

Therefore, all of the plurality of NMOSFETs 3 may be temporarily disposed first such that the first direction and the second direction are directed in the same direction or in the opposite directions to each other, and the relationship between the first direction and the second direction may be adjusted toward the disposition in which the first direction and the second direction are orthogonal to each other such that the maximum current value remains within a permissible range in the plurality of NMOSFETs 3.

For example, the relationship between the first direction and the second direction of each of the plurality of NMOSFETs 3 may be adjusted such that the difference between the maximum current value of the plurality of NMOSFETs 3 provided in the region over which the stress generated by the TSV 2 extends and the maximum current value of the NMOSFETs 3 upon which the stress does not act (namely, the NMOSFETs 3 provided in the region over which the stress generated by the TSV 2 does not extend) remains within a permissible range.

In this case, one NMOSFET 3 positioned in the region over which the stress generated by the TSV 2 extends and a different NMOSFET 3 positioned in the region over which the stress generated by the TSV 2 does not extend are disposed such that the channel directions are different from each other, namely, the channel directions are cross each other. It is to be noted that the one NMOSFET 3 is hereinafter referred to sometimes as first field-effect transistor or first N-channel field-effect transistor. Further, the different NMOSFET 3 is hereinafter referred to sometimes as second field-effect transistor or second N-channel field-effect transistor.

In this manner, by adjusting the relationship between the first direction and the second direction of the NMOSFETs 3 and disposing a plurality of NMOSFETs 3 in the region over which the stress generated by the TSV 2 extends, also where a plurality of NMOSFET 3 are disposed in the region over which the stress generated by the TSV 2 extends, such a situation can be suppressed that a variability of the current value of the NMOSFET 3 by an influence of the stress generated by the TSV 2 appears and degradation of a transistor characteristic can be suppressed.

Further, by the NMOSFETs 3 positioned in the region over which the stress generated by the TSV 2 extends and the NMOSFETs 3 positioned in the region over which the stress generated by the TSV 2 does not extend, variability of the current value can be suppressed and a transistor characteristic can be suppressed from being degraded.

Since a transistor characteristic can be suppressed from being degraded in this manner, a plurality of NMOSFETs 3 can be disposed also in the region over which the stress generated by the TSV 2 extends, and it is possible to dispose the NMOSFETs 3 in a high density to achieve increase of the density and increase of the degree of integration.

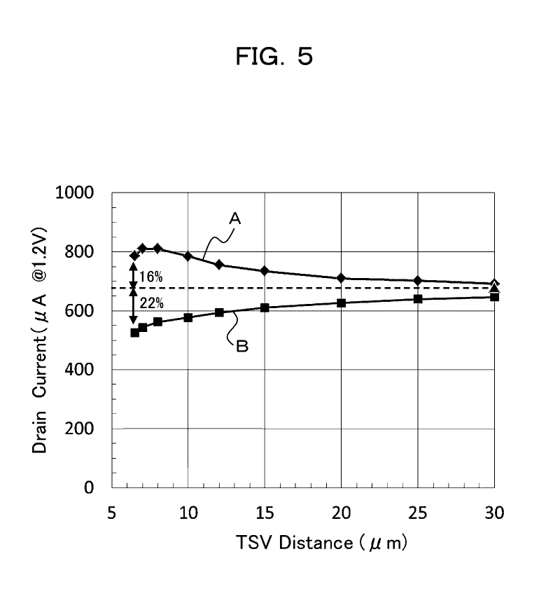

Here, FIG. 5 depicts a result when a distance dependency between a drain current value (Vg=Vd=1.2 V; maximum current value) of the NMOSFET 3 and the TSV 2 is analyzed.

Here, in FIG. 5, a solid line A indicates a variation of the drain current value with respect to the distance from the TSV 2 where the NMOSFET 3 is disposed such that, when tensile stress is generated along the direction (first direction) from the center of the TSV 2 toward the center of the channel of the NMOSFET 3, the channel direction (second direction) and the direction (first direction) from the center of the TSV 2 toward the center of the channel of the NMOSFET 3 coincide with each other (first direction=second direction). Here, the distance from the TSV 2 is the distance from the center of the TSV 2 to the center of the channel of the NMOSFET 3, namely, the distance in the first direction.

Further, in FIG. 5, a solid line B indicates a variation of the drain current value with respect to the distance from the TSV 2 where the NMOSFET 3 is disposed such that, when the tensile stress is generated along the direction (first direction) from the center of the TSV 2 toward the center of the channel of the NMOSFET 3, the channel direction (second direction) and the direction (first direction) from the center of the TSV 2 toward the center of the channel of the NMOSFET 3 are orthogonal to each other [first direction⊥(up tack) second direction]. Here, the distance from the TSV 2 is the distance from the center of the TSV 2 to the center of the channel of the NMOSFET 3, namely, the distance in the first direction.

It is to be noted, since, in this analysis, the distance from the TSV 2 is the distance from the center of the TSV 2 and the diameter of the TSV 2 here is set to approximately 10 μm, the distance from the TSV 2 is approximately 5 μm on a side face of the TSV 2. Further, the size (gate width) W of the NMOSFET 3 in the depthwise direction is determined as approximately 1 μm. Further, the drain current value of the NMOSFET 3 where the stress does not act (namely, of the NMOSFET 3 provided in the region over which the stress generated by the TSV 2 does not extend) is plotted with a triangular mark.

As depicted in FIG. 5, with the TSV 2 having the diameter of approximately 10 μm, there is an influence of the stress generated by the TSV 2 within a range in which the distance from the TSV 2 is approximately 20 μm or less. Further, where the NMOSFET 3 is disposed such as the first direction=the second direction, the drain current value increases in comparison with that in the case where the stress does not act. However, where the NMOSFET 3 is disposed such that the first direction⊥(up tack) the second direction, the drain current value decreases in comparison with that in the case where the stress does not act.

On the other hand, if the distance from the TSV 2 is approximately 20 μm or more, namely, if the NMOSFET 3 is spaced away from the TSV 2 by approximately 20 μm, then the influence of the stress generated by the TSV 2 disappears. In both of the case where the NMOSFET 3 is disposed such that the first direction=the second direction and the case where the NMOSFET 3 is disposed such that the first direction⊥(up tack) the second direction, the drain current value does not increase or decrease very much and the variability of the drain current value remains within a permissible range in comparison with the case where the stress does not act.

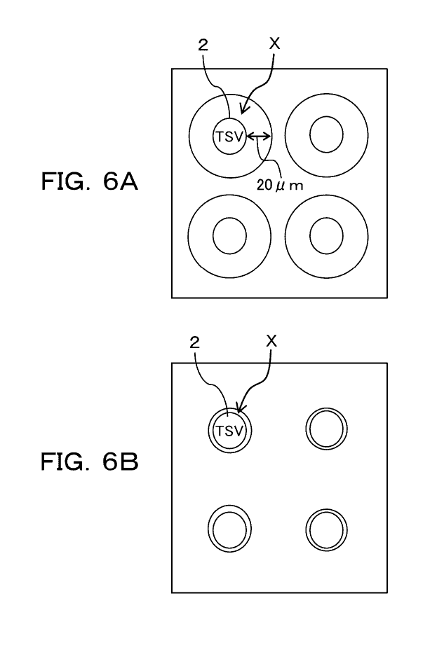

In this case, it may seem a recommendable idea not to dispose the NMOSFET 3 in the region over which the stress generated by the TSV 2 extends, namely, in the region around the TSV 2 in which the distance from the TSV 2 is approximately 20 μm (for example, refer to a region indicated by reference character X in FIG. 6A). However, for example, in the case where a great number of TSVs 2 are disposed in a pitch of approximately 50 μm in high density or the like or in a like case, if such an idea as just described is applied, then no NMOSFET 3 can be disposed around the TSV 2.

In contrast, if the relationship between the first direction and the second direction of the NMOSFET 3 is adjusted and the NMOSFET 3 is disposed in such a manner as described above, then such a situation can be suppressed that a variability of the current values of the NMOSFETs 3 is caused by an influence of the stress generated by the TSV 2. Therefore, the NMOSFET 3 can be disposed also in the region over which the stress generated by the TSV 2 extends and it is possible to dispose NMOSFETs in high density so as to achieve increase of the density and increase of the degree of integration. For example, the NMOSFETs 3 can be disposed except, for example, for a region in which the distance from a side face of the TSV 2 is approximately 2 μm (for example, refer to a region indicated by reference character X in FIG. 6B), and it is possible to achieve increase of the density and increase of the degree of integration.

Further, for example, where a plurality of PMOSFETs 4 are provided in the region over which the stress generated by the TSV 2 extends, the plurality of PMOSFETs 4 may be disposed in a state in which the relationship between the channel direction (second direction) and the direction (first direction) from the center of the TSV 2 toward the center of the channel of the PMOSFETs 4 is adjusted such that the maximum current values of the plurality of PMOSFETs 4 remain within a permissible range.

In this case, one PMOSFET 4 and a different PMOSFET 4 positioned in the region over which the stress generated by the TSV 2 extends are disposed such that the channel directions are different from each other. Further, the maximum current values of the one PMOSFET 4 and the different PMOSFET 4 remain within the permissible range. It is to be noted that the one PMOSFET 4 is hereinafter referred to sometimes as first field-effect transistor or first P-channel field-effect transistor. Further, the different PMOSFET 4 is hereinafter referred to sometimes as second field-effect transistor or second P-channel field-effect transistor.

Here, where tensile stress is generated along the first direction, if the PMOSFETs 4 are disposed such that the first direction and the second direction are orthogonal to each other, then the maximum current value can be made highest. Further, if the relationship between the first direction and the second direction of the PMOSFET 4 (namely, an angle of the channel direction of the PMOSFET 4 with respect to the direction from the center of the TSV 2 toward the center of the channel of the PMOSFET 4; gate angle of the PMOSFET 4) is adjusted from the disposition in which the first direction and the second direction are orthogonal to each other toward the disposition in which the first direction and the second direction are directed in the same direction or in the opposite directions to each other, then the maximum current value can be decreased.

Therefore, all of the plurality of PMOSFETs 4 may be temporarily disposed first such that the first direction and the second direction are orthogonal to each other and the relationship between the first direction and the second direction of each of the plurality of PMOSFETs 4 may be adjusted toward the disposition in which the first direction and the second direction are directed in the same direction or in the opposite directions to each other such that the maximum current value remains within the permissible range.

For example, the relationship between the first direction and the second direction of each of the plurality of PMOSFETs 4 may be adjusted such that the difference between the maximum current value of the plurality of PMOSFETs 4 provided in the region over which the stress generated by the TSV 2 extends and the maximum current value of the PMOSFET 4 upon which the stress does not act (namely, the PMOSFET 4 provided in the region over which the stress generated by the TSV 2 does not extend) remains within the permissible range.

In this case, one PMOSFET 4 positioned in the region over which the stress generated by the TSV 2 extends and a different PMOSFET 4 positioned in the region over which the stress generated by the TSV 2 does not extend are disposed such that the channel directions are different from each other, namely, the channel directions are cross each other. It is to be noted that the one PMOSFET 4 is hereinafter referred to sometimes as first field-effect transistor or first P-channel field-effect transistor. Further, the different PMOSFET 4 is hereinafter referred to sometimes as second field-effect transistor or second P-channel field-effect transistor.

In this manner, if the relationship between the first direction and the second direction of the PMOSFETs 4 is adjusted and a plurality of PMOSFETs 4 are disposed in the region over which the stress generated by the TSV 2 extends, then also where a plurality of PMOSFETs 4 are disposed in the region over which the stress generated by the TSV 2 extends, such a situation can be suppressed that a variability of the current values of the PMOSFETs 4 caused by an influence of the stress generated by the TSV 2 appears and a transistor characteristic can be suppressed from being degraded.

Further, it is possible to suppress the current value from being varied between the PMOSFETs 4 positioned in the region over which the stress generated by the TSV 2 extends and the PMOSFETs 4 positioned in the region over which the stress generated by the TSV 2 does not extend and thereby to suppress a transistor characteristic from being degraded.

In this manner, since it is possible to suppress a transistor characteristic from being degraded, a plurality of PMOSFETs 4 can be disposed also in the region over which the stress generated by the TSV 2 extends, and therefore, it is possible to dispose the PMOSFETs 4 in high density so as to achieve increase of the density and increase of the degree of integration.

Incidentally, also it is possible to couple the gates of the NMOSFET 3 and PMOSFET 4 positioned in the region over which the stress generated by the TSV 2 extends with each other configure a CMOS (Complementary MOS) inverter 5 from the NMOSFET 3 and the PMOSFET 4 (for example, refer to FIGS. 1A, 1B and 4). It is to be noted that the CMOS inverter 5 is hereinafter referred to sometimes as inverter simply.

In this case, it is preferable to set the difference between the maximum current values of the NMOSFET 3 and the PMOSFET 4 so as to remain within the permissible range by adjusting the channel directions of the NMOSFET 3 and the PMOSFET 4 positioned in the region over which the stress generated by the TSV 2 extends, namely, by adjusting the angle at which the channel direction of the NMOSFET 3 and the channel direction of the PMOSFET 4 cross with each other. Especially, it is more preferable to adjust the maximum current value of the NMOSFET 3 and the maximum current value of the PMOSFET 4 by adjusting the channel directions of the NMOSFET 3 and the PMOSFET 4 positioned in the region over which the stress generated by the TSV 2 extends. Consequently, the variability of the maximum current values of the NMOSFET 3 and the PMOSFET 4 can be suppressed and a characteristic of the CMOS inverter 5 can be enhanced. It is to be noted that, by adding such adjustment of the channel directions of the NMOSFET 3 and the PMOSFET 4 as described above as a design parameter, design with a higher degree of accuracy can be achieved and a characteristic of the CMOS inverter 5 can be enhanced. Further, to adjust the angle at which the channel direction of the NMOSFET 3 and the channel direction of the PMOSFET 4 cross with each other is also to adjust the angle between the gate of the NMOSFET 3 and the gate of the PMOSFET 4.

In this case, the NMOSFET 3 and the PMOSFET 4 positioned in the region over which the stress generated by the TSV 2 extends are disposed such that the channel directions are different from each other, namely, the channel directions cross with each other. In particular, the NMOSFET 3 and the PMOSFET 4 are disposed such that, in accordance with the positions of them with respect to the TSV 2 that is a stress generation source, the channel directions are different from each other, namely, the channel directions cross with each other.

It is to be noted that an NMOSFET and a PMOSFET configuring a CMOS inverter are provided generally such that the gates are formed as a common gate extending linearly in one direction (refer to FIG. 9). In this case, the NMOSFET and the PMOSFET are disposed such that the channel directions are directed in parallel to each other. Therefore, it may seem recommendable to dispose the NMOSFETs and the PMOSFETs in all regions including a region over which the stress generated by the TSV extends and another region over which the stress generated by the TSV does not extend and configuring a CMOS inverter such that the channel directions are directed in parallel to each other. However, if such disposition as just described is applied, then a variability of a characteristic of the CMOS inverter arises. Thus, the variability of a characteristic of the CMOS inverter 5 can be suppressed by disposing the NMOSFET 3 and the PMOSFET 4 provided in the region over which the stress generated by the TSV 2 extends and configuring the CMOS inverter 5 such that the channel directions cross with each other and by disposing the NMOSFET 3 and the PMOSFET 4 provided in the region over which the stress generated by the TSV 2 does not extend and configuring the CMOS inverter 5 such that the channel directions are directed in parallel to each other (for example, refer to FIG. 4).

Further, by adjusting the size (gate width) W of the NMOSFETs 3 and the PMOSFETs 4 in the depthwise direction, also it is possible to suppress the variability of a characteristic of the plurality of CMOS inverters 5 provided in all regions including the region over which the stress generated by the TSV 2 extends and the region over which the stress generated by the TSV 2 does not extend. In particular, by adjusting the size (gate width) W of the NMOSFETs 3 and the PMOSFETs 4 in the depthwise direction, the maximum current values of the NMOSFETs 3 and the PMOSFETs 4 positioned in the region over which the stress generated by the TSV 2 extends match with the maximum current values of the NMOSFETs 3 and the PMOSFETs 4 when the stress does not act upon them (namely, of the NMOSFETs 3 and PMOSFETs 4 positioned in the region over which the stress generated by the TSV 2 does not extend). Consequently, also it is possible to suppress the variability of a characteristic of the plurality of CMOS inverters 5 provided in all regions including the region over which the stress generated by the TSV 2 extends and the region over which the stress generated by the TSV 2 does not extend.

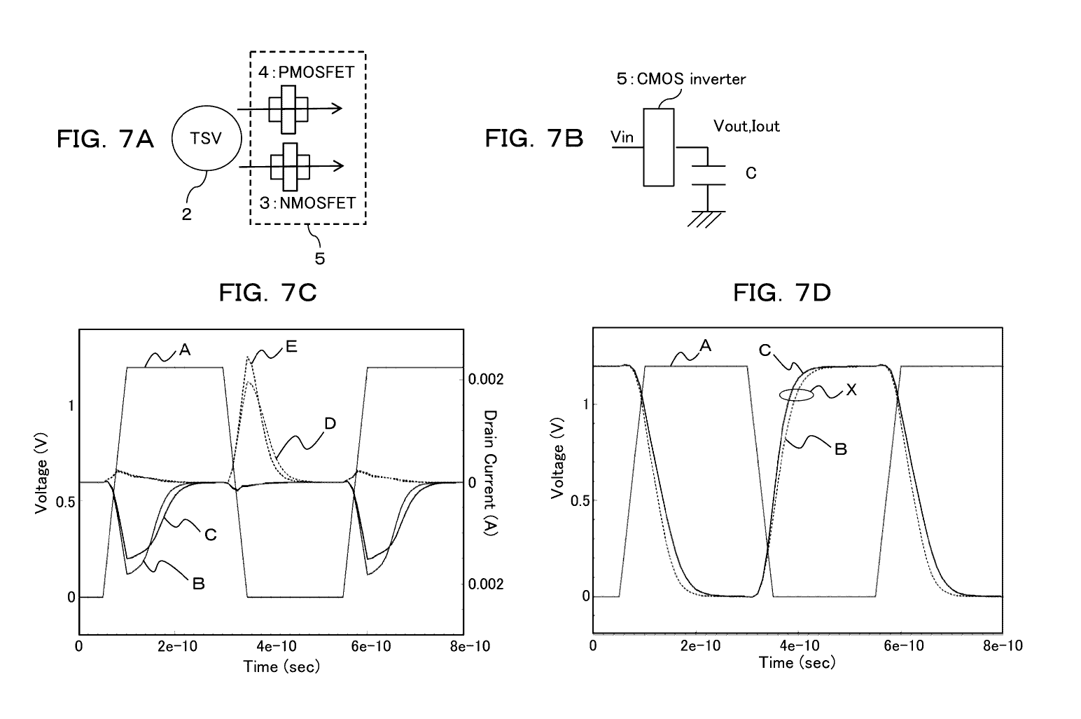

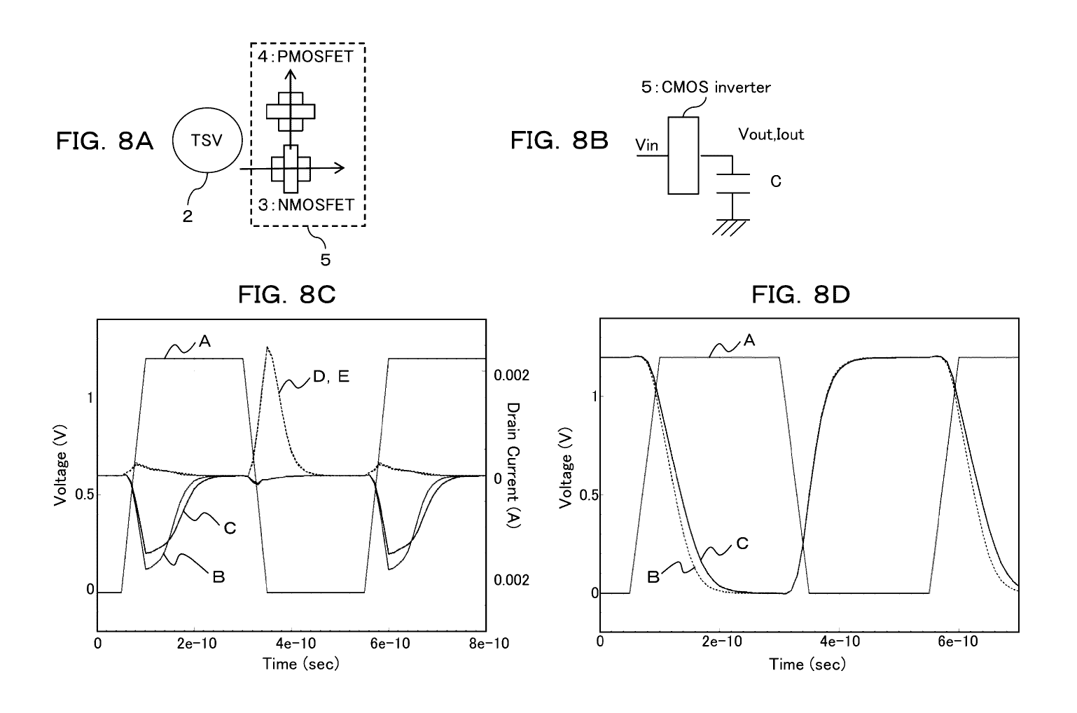

Here, the disposition dependency of a characteristic of the CMOS inverter 5 was analyzed by simulation in regard to the case of the embodiment described above, namely, to the case where the NMOSFET 3 and the PMOSFET 4 provided in the region over which the stress generated by the TSV 2 extends and configuring the CMOS inverter 5 are disposed such that the channel directions are orthogonal to each other, and also to the case of a comparative example, namely, to the case where the NMOSFET 3 and the PMOSFET 4 provided in the region over which the stress generated by the TSV 2 extends and configuring the CMOS inverter 5 are disposed such that the channel directions are directed in parallel to each other, and such illustrated as depicted in FIGS. 7A to 7D and FIGS. 8A to 8D were obtained. It is to be noted that, in the disposition of the embodiment described above, the channel direction of the PMOSFET 4 configuring the CMOS inverter 5 is rotated by 90 degrees with respect to that in the disposition of the comparative example.

Here, FIG. 7A is a schematic view depicting disposition of the NMOSFET 3 and the PMOSFET 4 configuring the CMOS inverter 5 in the comparative example. Further, FIG. 7B is a view depicting a circuit configuration of the CMOS inverter 5 in the comparative example. Further, FIGS. 7C and 7D illustrates results when an influence of the stress generated by the TSV 2 on inverter characteristics (output current Iₒᵤₜ and output voltage Vₒᵤₜ) in the comparative example is analyzed by simulation.

In particular, FIG. 7C depicts a variation of the output current Iₒᵤₜ with respect to the input voltage Vᵢₙ (here, an input waveform of 2 GHz) to the CMOS inverter 5.

Here, in FIG. 7C, a solid line A indicates a variation of the input voltage Vᵢₙ of the CMOS inverter 5 and solid lines B and C and broken lines D and E indicate variations of the output current Iₒᵤₜ of the CMOS inverter. Further, in FIG. 7C, the solid line B indicates output current of the NMOSFET 3 provided in the region over which the stress generated by the TSV 2 extends and configuring the CMOS inverter 5 (here, the NMOSFET 3 provided at a position at which the distance from a side face of the TSV 2 is approximately 2 μm). Further, in FIG. 7C, the solid line C indicates output current of the NMOSFET 3 configuring the CMOS inverter 5 on which the stress does not act, namely, the NMOSFET 3 provided in the region over which the stress generated by the TSV 2 does not extend and configuring the CMOS inverter 5. Further, in FIG. 7C, the broken line D indicates output current of the PMOSFET 4 provided in the region over which the stress generated by the TSV 2 extends and configuring the CMOS inverter 5. Further, in FIG. 7C, the broken line E indicates output current of the PMOSFET 4 configuring the CMOS inverter 5 on which the stress does not act, namely, the PMOSFET 4 provided in the region over which the stress generated by the TSV 2 does not extend and configuring the CMOS inverter 5.

Further, FIG. 7D depicts a variation of the output voltage Vₒᵤₜ with respect to the input voltage Vᵢₙ (here, an input waveform of 2 GHz) of the CMOS inverter 5.

Here, in FIG. 7D, a solid line A indicates a variation of the input voltage Vᵢₙ of the CMOS inverter 5. Further, in FIG. 7D, a broken line B indicates a variation of the output voltage Vₒᵤₜ of the CMOS inverter 5 provided in the region over which the stress generated by the TSV 2 extends (here, of the CMOS inverter 5 provided at a position at which the distance from a side face of the TSV 2 is approximately 2 μm). Further, in FIG. 7D, a solid line C indicates a variation of the output voltage Vₒᵤₜ of the CMOS inverter 5 on which the stress does not act, namely, of the CMOS inverter 5 provided in the region over which the stress generated by the TSV 2 does not extend.

Further, FIGS. 8A to 8D illustrate results when an influence of the stress generated by the TSV 2 on inverter characteristics (output current and output voltage) is analyzed by simulation in the case of the embodiment described above, namely, in the case where the NMOSFET 3 and the PMOSFET 4 provided in the region over which the stress generated by the TSV 2 extends and configuring the CMOS inverter 5 are disposed such that the channel directions are orthogonal to each other.

Here, FIG. 8A is a schematic view depicting deposition of the NMOSFET 3 and the PMOSFET 4 configuring the CMOS inverter 5 of the embodiment described above. Further, FIG. 8B is a view depicting a circuit configuration of the CMOS inverter 5 of the embodiment described above. Further, FIGS. 8C and 8D illustrate results when an influence of the stress generated by the TSV 2 on inverter characteristics (output current Iₒᵤₜ and output voltage Vₒᵤₜ) is analyzed by simulation in the case of the embodiment described above.

In particular, FIG. 8C depicts a variation of the output current Iₒᵤₜ with respect to the input voltage Vᵢₙ (here, an input waveform of 2 GHz) of the CMOS inverter 5.

Here, in FIG. 8C, a solid line A indicates a variation of the input voltage Vᵢₙ of the CMOS inverter 5 and solid lines B and C and broken lines D and E indicate the output current Iₒᵤₜ of the CMOS inverter 5. Further, in FIG. 8C, the solid line B indicates output current of the NMOSFET 3 provided in the region over which the stress generated by the TSV 2 extends and configuring the CMOS inverter 5 (here, of the NMOSFET 3 provided at a position at which the distance from a side face of the TSV 2 is approximately 2 μm). Further, in FIG. 8C, the solid line C indicates output current of the NMOSFET 3 configuring the CMOS inverter 5 on which the stress does not act, namely, of the NMOSFET 3 provided in the region over which the stress generated by the TSV 2 does not extend and configuring the CMOS inverter 5. Further, in FIG. 8C, the broken line D indicates output current of the PMOSFET 4 provided in the region over which the stress generated by the TSV 2 extends and configuring the CMOS inverter 5. Further, in FIG. 8C, the broken line E indicates output current of the PMOSFET 4 configuring the CMOS inverter 5 on which the stress does not act, namely, of the PMOSFET 4 provided in the region over which the stress generated by the TSV 2 does not extend and configuring the CMOS inverter 5.

Further, FIG. 8D depicts a variation of the output voltage Vₒᵤₜ with respect to the input voltage Vᵢₙ (here, an input waveform of 2 GHz) of the CMOS inverter 5.

Here, in FIG. 8D, a solid line A indicates a variation of the input voltage Vᵢₙ of the CMOS inverter 5. Further, in FIG. 8D, a broken line B indicates a variation of the output voltage Vₒᵤₜ of the CMOS inverter 5 provided in the region over which the stress generated by the TSV 2 extends (here, the CMOS inverter 5 provided at a position at which the distance from a side face of the TSV 2 is approximately 2 μm). Further, in FIG. 8D, a solid line C indicates a variation of the output voltage Vₒᵤₜ of the CMOS inverter 5 on which the stress does not act, namely, of the CMOS inverter 5 provided in the region over which the stress generated by the TSV 2 does not extend.

In the disposition of the comparative example, as indicated by the solid lines B and C in FIG. 7C, output current of the NMOSFET 3 provided in the region over which the stress generated by the TSV 2 extends and configuring the CMOS inverter 5 does not coincide with output current of the NMOSFET 3 configuring the CMOS inverter 5 on which the stress does not act, namely, of the NMOSFET 3 provided in the region over which the stress generated by the TSV 2 does not extend and configuring the CMOS inverter 5, and is varied.

Further, in FIG. 7C, as indicated by the broken lines D and E, output current of the PMOSFET 4 provided in the region over which the stress generated by the TSV 2 extends and configuring the CMOS inverter 5 does not coincide with output current of the PMOSFET 4 configuring the CMOS inverter 5 on which the stress does not act, namely, of the PMOSFET 4 provided in the region over which the stress generated by the TSV 2 does not extend and configuring the CMOS inverter 5, and therefore is varied.

Further, in FIG. 7D, as indicated by the broken line B and the solid line C, an output voltage of the CMOS inverter 5 provided in the region over which the stress generated by the TSV 2 extends does not coincide, in both of the operation region of the NMOSFET 3 and the operation region of the PMOSFET 4, with an output voltage of the CMOS inverter 5 on which the stress does not act, namely, of the CMOS inverter 5 provided in the region over which the stress generated by the TSV 2 does not extend, and therefore is varied, and some delay (here, a delay by approximately 15 ps in a region indicated by reference character X in FIG. 7D) occurs.

In this manner, if the NMOSFET 3 and the PMOSFET 4 configuring the CMOS inverter 5 are provided in the region over which the stress generated by the TSV 2 extends, then the output current of both of the NMOSFET 3 and the PMOSFET 4 configuring the CMOS inverter 5 is varied, and some delay occurs with the output voltage.

In contrast, in the disposition of the embodiment described above, the channel direction of the PMOSFET 4 configuring the CMOS inverter 5 is rotated by 90 degrees such that the current value of the PMOSFET 4 positioned in the region over which the stress generated by the TSV 2 extends exhibits the highest level in comparison with that in the disposition in the comparative example.

Here, the size (gate width) W of the PMOSFET 4 in the depthwise direction is adjusted such that the maximum current value of the PMOSFET 4 positioned in the region over which the stress generated by the TSV 2 extends matches with the maximum current value of the PMOSFET 4 where the stress does not act (namely, of the PMOSFET 4 provided in the region over which the stress generated by the TSV 2 does not extend).

As a result, in the deposition of the embodiment described above, as indicated by the broken lines D and E in FIG. 8C, the output current (output current waveform) of the PMOSFET 4 provided in the region over which the stress generated by the TSV 2 extends and configuring the CMOS inverter 5 coincides with output current (output current waveform) of the PMOSFET 4 configuring the CMOS inverter Son which the stress does not act, namely, of the PMOSFET 4 provided in the region over which the stress generated by the TSV 2 does not extend and configuring the CMOS inverter 5, and therefore, the variability is suppressed.

Further, as indicated by the broken line B and the solid line C in FIG. 8D, the output voltage (output voltage waveform) of the CMOS inverter 5 provided in the region over which the stress generated by the TSV 2 extends coincides with the output voltage (output voltage waveform) of the CMOS inverter 5 on which the stress does not act, namely, of the CMOS inverter 5 provided in the region over which the stress generated by the TSV 2 does not extend, and therefore, the variability is suppressed and a delay does not occur.

In this manner, in the disposition of the embodiment described above, the variability of a characteristic of the CMOS inverter 5, namely, of the output current and the output voltage of the CMOS inverter 5, can be suppressed in comparison with the disposition of the comparative example.

It is to be noted that, in the disposition of the embodiment described above and the disposition of the comparative example, the NMOSFET 3 positioned in the region over which the stress generated by the TSV 2 extends and configuring the CMOS inverter 5 is disposed such that the current value exhibits the highest level, and the disposition of the NMOSFET 3 configuring the CMOS inverter 5 is same as in the disposition in the embodiment described above and the disposition in the comparative example.

However, the size (gate width) W of the NMOSFET 3 in the depthwise direction is not adjusted such that the maximum current value of the NMOSFET 3 positioned in the region over which the stress generated by the TSV 2 extends matches with the maximum current value of the NMOSFET 3 on which the stress does not act (namely, of the NMOSFET 3 provided in the region over which the stress generated by the TSV 2 does not extend).

Therefore, the variability of the output current of the NMOSFET 3 configuring the CMOS inverter 5 is not suppressed, and also the variability of the output voltage of the CMOS inverter 5 is not suppressed in the operation region of the NMOSFET 3.

Accordingly, by adjusting the size (gate width) W of the NMOSFET 3 in the depthwise direction such that the maximum current value of the NMOSFET 3 positioned in the region over which the stress generated by the TSV 2 extends matches with the maximum current value of the NMOSFET 3 on which the stress does not act (namely, of the NMOSFET 3 provided in the region over which the stress generated by the TSV 2 does not extend), the variability of the output current of the NMOSFET 3 configuring the CMOS inverter 5 is suppressed similarly as in the case of the PMOSFET 4 described above. Further, also with regard to the output voltage of the CMOS inverter 5, the variability can be suppressed in the operation region of the NMOSFET 3.

Further, in the disposition of the embodiment described above and the disposition of the comparative example, it is preferable to suppress, by adjusting the channel directions of the NMOSFET 3 and the PMOSFET 4 positioned in the region over which the stress generated by the TSV 2 extends such that the difference between the maximum current values of the NMOSFET 3 and the PMOSFET 4 remains within a permissible range, the variability of the maximum current values of the NMOSFET 3 and the PMOSFET 4 configuring the CMOS inverter 5 and enhance the characteristic of the CMOS inverter 5.

Now, a fabrication method for the semiconductor device according to the present embodiment is described.

The fabrication method for the semiconductor device according to the present embodiment includes a step of providing a stress generation source (here, TSV 2) that generates stress on the semiconductor substrate 1 (here, silicon substrate) on the semiconductor substrate 1 and a step of providing a first field-effect transistor (here, NMOSFET 3) and a second field-effect transistor (here, PMOSFET 4) on the semiconductor substrate 1.

Then, at the step of providing a first field-effect transistor and a second field-effect transistors, the first field-effect transistor and the second field-effect transistor are disposed such that the channel directions from the source toward the drain are different from each other in accordance with positions thereof with respect to the stress generation source.

Especially, the step of providing a first field-effect transistor and a second field-effect transistor is a step of disposing an N-channel field-effect transistor (here, an NMOSFET 3) and a P-channel field-effect transistor (here, a PMOSFET 4) that configure an inverter (here, a CMOS inverter 5).

Then, the step of disposing an N-channel field-effect transistor and a P-channel field-effect transistor includes a step of temporarily disposing the N-channel field-effect transistor such that a channel direction (second direction) and a direction (first direction) from the center of the stress generation source toward the center of the channel of the N-channel field-effect transistor coincide with each other and temporarily disposing the P-channel field-effect transistor such that the channel direction (second direction) and the direction (first direction) from the center of the stress generation source toward the center of the channel of the P-channel field-effect transistor are orthogonal to each other, and a step of adjusting the channel directions of the N-channel field-effect transistor or the P-channel field-effect transistor such that the difference between the maximum current values of the N-channel field-effect transistor and the P-channel field-effect transistor is within a permissible range.

In particular, at the design stage of the CMOS inverter 5, after the NMOSFET 3 and the PMOSFET 4 configuring the CMOS inverter 5 are temporarily disposed such that the current values are highest in the region over which the stress generated by the TSV 2 extends, the channel directions of the NMOSFET 3 and the PMOSFET 4 may be adjusted in such a manner as described below.

It is to be noted here that the present embodiment is described taking, as an example, a case where, by adjusting gate angle of the NMOSFET 3 or the PMOSFET 4, the channel directions of the NMOSFET 3 or the PMOSFET 4 are adjusted.

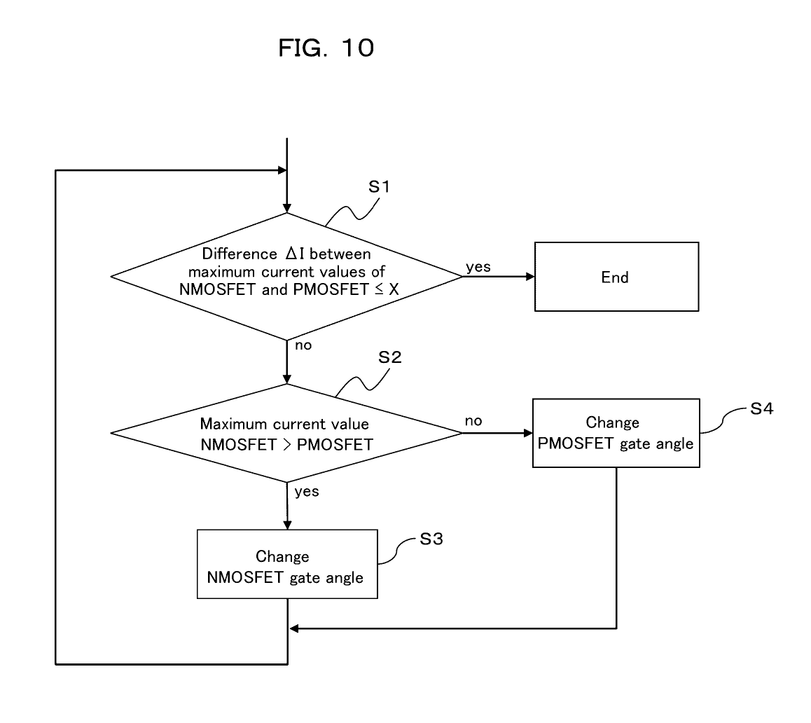

First, as depicted in FIG. 10, the difference (ΔI) between the maximum current values (Vg=Vd=maximum voltage) of the NMOSFET 3 and the PMOSFET 4 is calculated, and it is decided whether or not the difference is equal to or smaller than a fixed value (X) (step S1)

If it is decided as a result of the decision that the difference between the maximum current values of the NMOSFET 3 and the PMOSFET 4 is greater than the fixed value, then the processing advances to a No route and it is decided whether or not the maximum current value of the NMOSFET 3 is higher than the maximum current value of the PMOSFET 4 (step S2).

Then, if it is decided that the maximum current value of the NMOSFET 3 is higher than the maximum current value of the PMOSFET 4, then the processing advances to a YES route and the gate angle of the NMOSFET 3 is adjusted (changed) such that the maximum current value of the NMOSFET 3 approaches the maximum current value of the PMOSFET 4 (step S3).

Here, by adjusting the gate angle of the NMOSFET 3 such that the channel direction approaches a direction in which the first direction and the second direction are orthogonal to each other from a state in which the NMOSFET 3 is temporarily disposed such that the first direction and the second direction of the NMOSFET 3 coincide with each other, the maximum current value of the NMOSFET 3 is decreased so as to approach the maximum current value of the PMOSFET 4.

On the other hand, if it is decided that the maximum current value of the NMOSFET 3 is not greater than the maximum current value of the PMOSFET 4, namely, that the maximum current value of the PMOSFET 4 is equal to or higher than the maximum current value of the NMOSFET 3, then the processing advances to a NO route and the gate angle of the PMOSFET 4 is adjusted (changed) (step S4).

Here, by adjusting the gate angle of the PMOSFET 4 such that it approaches a direction in which the first direction and the second direction coincide with each other from a state in which the PMOSFET 4 is temporarily disposed such that the first direction and the second direction are orthogonal to each other, the maximum current value of the PMOSFET 4 is decreased so as to approach the maximum current value of the NMOSFET 3.

Therefore, the processes at steps Si to S4 are repetitively performed until it is decided at step Si that the difference between the maximum current values of the NMOSFET 3 and the PMOSFET 4 is equal to or smaller than the fixed value.

Then, if it is decided at step Si that the difference between the maximum current values of the NMOSFET 3 and the PMOSFET 4 is equal to or smaller than the fixed value, then the processing advances to a YES route and the processing is ended.

In this manner, by adjusting the gate angle of the NMOSFET 3 or the PMOSFET 4 when the NMOSFET 3 and the PMOSFET 4 configuring the CMOS inverter 5 are disposed at the design stage of the CMOS inverter 5, the channel direction of the NMOSFET 3 or the PMOSFET 4 can be adjusted such that the difference between the maximum current values of the NMOSFET 3 and the PMOSFET 4 remains within the permissible range. Consequently, the variability of the maximum current value of the NMOSFET 3 and the PMOSFET 4 can be suppressed and a characteristic of the CMOS inverter 5 can be enhanced.

It is to be noted here that, while description is given taking, as an example, a case where a higher one of the maximum current value of the NMOSFET 3 and the maximum current value of the PMOSFET 4 is matched with a lower one of the maximum current values, the present technology is not limited to this. For example, the maximum current value of the NMOSFET 3 and the maximum current value of the PMOSFET 4 may be matched with an arbitrary current value.

Further, while description here is given taking, as an example, a case where adjustment is performed such that the difference between the maximum current values of the NMOSFET 3 and the PMOSFET 4 falls within a permissible range, the present technology is not limited to this. Ideally, the CMOS inverter 5 is preferably designed such that the maximum current value (current characteristic) of the NMOSFET 3 and the maximum current value (current characteristic) of the PMOSFET 4 are equal to each other. Therefore, adjustment may be performed such that the difference between the maximum current values of the NMOSFET 3 and the PMOSFET 4 becomes zero, namely, the maximum current values of the NMOSFET 3 and the PMOSFET 4 become coincident with each other.

Accordingly, with the semiconductor device and the fabrication method therefor according to the present embodiment, there is an advantage that the transistor characteristic can be suppressed from degrading depending upon the position with respect to the TSV 2 that is a stress generation source.

It is to be noted that, while the stress generation source in the embodiment described above is a through via (particularly, a TSV) extending through a semiconductor substrate, the present technology is not limited to this and the stress generation source may be a bump provided on a semiconductor substrate. In this case, the TSV (stress generation source) in the embodiment and the modification described above may be read as a bump. Consequently, similarly as in the cases of the embodiment and modification described above, a transistor characteristic can be suppressed from being degraded depending upon the position with respect to a bump that serves as a stress generation source.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor device, comprising:
a semiconductor substrate;
a stress generation source that is provided on the semiconductor substrate and generates stress in the semiconductor substrate; and
a first field-effect transistor and a second field-effect transistor provided on the semiconductor substrate; wherein
the first field-effect transistor and the semiconductor substrate are disposed such that channel directions from a source toward a drain are different from each other in response to positions with respect to the stress generation source.

2. The semiconductor device according to claim 1, wherein the first field-effect transistor is an N channel type field-effect transistor;
the second field-effect transistor is a P channel type field-effect transistor; and
the N channel type field-effect transistor and the P channel type field-effect transistor are positioned within a region over which the stress generated by the stress generation source extends and are disposed such that the channel directions are different from each other.

3. The semiconductor device according to claim 1, wherein the first field-effect transistor is a first N channel type field-effect transistor;
the second field-effect transistor is a second N channel type field-effect transistor; and
the first N channel type field-effect transistor and the second N channel type field-effect transistor are positioned within a region over which the stress generated by the stress generation source extends and are disposed such that the channel directions are different from each other.

4. The semiconductor device according to claim 1, wherein the first field-effect transistor is a first P channel type field-effect transistor;
the second field-effect transistor is a second P channel type field-effect transistor; and
the first P channel type field-effect transistor and the second P channel type field-effect transistor are positioned within a region over which the stress generated by the stress generation source extends and are disposed such that the channel directions are different from each other.

5. The semiconductor device according to claim. 1, wherein the first field-effect transistor is a first N channel type field-effect transistor;
the second field-effect transistor is a second N channel type field-effect transistor; and
the first N channel type field-effect transistor is positioned within a region over which the stress generated by the stress generation source extends while the second N channel type field-effect transistor is positioned within a region over which the stress generated by the stress generation source does not extend, and the first N channel type field-effect transistor and the second N channel type field-effect transistor are disposed such that the channel directions are different from each other.

6. The semiconductor device according to claim 1, wherein the first field-effect transistor is a first P channel type field-effect transistor;
the second field-effect transistor is a second P channel type field-effect transistor; and
the first P channel type field-effect transistor is positioned within a region over which the stress generated by the stress generation source extends while the second P channel type field-effect transistor is positioned within a region over which the stress generated by the stress generation source does not extend, and the first P channel type field-effect transistor and the second P channel type field-effect transistor are disposed such that the channel directions are different from each other.

7. The semiconductor device according to claim 2, further comprising a different N channel type field-effect transistor and a different P channel type field-effect transistor positioned within a region over which the stress generated by the stress generation source does not extend; and
the different N channel type field-effect transistor and the different P channel type field-effect transistor are disposed such that the channel directions are in parallel to each other.

8. The semiconductor device according to claim 2, wherein, where tensile stress is generated in a direction from the center of the stress generation source toward the center of the channel of the N channel type field-effect transistor, the N channel type field-effect transistor is disposed such that the channel direction and the direction from the center of the stress generation source toward the center of a channel of the N channel type field-effect transistor coincide with each other.

9. The semiconductor device according to claim 2, wherein, where tensile stress is generated in a direction from the center of the stress generation source toward the center of the channel of the P channel type field-effect transistor, the P channel type field-effect transistor is disposed such that the channel direction and the direction from the center of the stress generation source toward the center of the channel of the P channel type field-effect transistor are orthogonal to each other.

10. The semiconductor device according to claim 3, wherein the first N channel type field-effect transistor is disposed such that, where tensile stress is generated in a direction from the center of the stress generation source toward the center of the channel of the first N channel type field-effect transistor, the channel direction and the direction from the center of the stress generation source toward the center of the channel of the first N channel type field-effect transistor coincide with each other; and
the second N channel type field-effect transistor is disposed such that, where tensile stress is generated in a direction from the center of the stress generation source toward the center of the channel of the second N channel type field-effect transistor, the channel directions and the direction from the center of the stress generation source toward the center of the channel of the second N channel type field-effect transistor coincide with each other.

11. The semiconductor device according to claim. 4, wherein the first P channel type field-effect transistor is disposed such that, where tensile stress is generated in a direction from the center of the stress generation source toward the center of the channel of the first P channel type field-effect transistor, the channel direction and the direction from the center of the stress generation source toward the center of the channel of the first P channel type field-effect transistor are orthogonal to each other; and
the second P channel type field-effect transistor is disposed such that, where tensile stress is generated in a direction from the center of the stress generation source toward the center of the channel of the second P channel type field-effect transistor, the channel directions and the direction from the center of the stress generation source toward the center of the channel of the second P channel type field-effect transistor are orthogonal to each other.

12. The semiconductor device according to claim. 5, wherein the first N channel type field-effect transistor is disposed such that, where tensile stress is generated in a direction from the center of the stress generation source toward the center of the channel of the first N channel type field-effect transistor, the channel direction and the direction from the center of the stress generation source toward the center of the channel of the first N channel type field-effect transistor coincide with each other.

13. The semiconductor device according to claim 6, wherein the first P channel type field-effect transistor is disposed such that, where tensile stress is generated in a direction from the center of the stress generation source toward the center of the channel of the first P channel type field-effect transistor, the channel direction and the direction from the center of the stress generation source toward the center of the channel of the first P channel type field-effect transistor are orthogonal to each other.

14. The semiconductor device according to claim 2, wherein an inverter is configured from the N channel type field-effect transistor and the P channel type field-effect transistor; and
a difference between maximum current values of the N channel type field-effect transistor and the P channel type field-effect transistor is within a permissible range.

15. The semiconductor device according to claim 3, wherein maximum current values of the first N channel type field-effect transistor and the second N channel type field-effect transistor are within a permissible range.

16. The semiconductor device according to claim 4, wherein maximum current values of the first P channel type field-effect transistor and the second P channel type field-effect transistor are within a permissible range.

17. The semiconductor device according to claim. 1, wherein the stress generation source is a through via extending through the semiconductor substrate or a bump provided on the semiconductor substrate.

18. The semiconductor device according to claim 1, wherein the semiconductor substrate is a silicon substrate; and
the stress generation source has a thermal expansion coefficient different from that of silicon that is a material of the silicon substrate.

19. A fabrication method for a semiconductor device, comprising:
providing, on the semiconductor substrate, a stress generation source that generates stress in a semiconductor substrate; and
providing a first field-effect transistor and a second field-effect transistor on the semiconductor substrate; wherein
at the providing the first field-effect transistor and the second field-effect transistor, the first field-effect transistor and the second field-effect transistor are disposed such that channel directions from a source toward a drain are different from each other in response to a position of the stress generation source.

20. The fabrication method for a semiconductor device according to claim 19, wherein the disposing the first field-effect transistor and the second field-effect transistor is disposing an N channel type field-effect transistor and a P channel type field-effect transistor that configure an inverter; and
the disposing the N channel type field-effect transistor and the P channel type field-effect transistor includes:
provisionally disposing the N channel type field-effect transistor in a region over which stress generated by the stress generation source extends such that the channel direction and a direction from the center of the stress generation source toward the center of the channel of the N channel type field-effect transistor coincide with each other and provisionally disposing the P channel type field-effect transistor such that the channel direction and a direction from the center of the stress generation source toward the center of the channel of the N channel type field-effect transistor are orthogonal to each other; and
adjusting the channel direction of the N channel type field-effect transistor or the P channel type field-effect transistor such that a difference between maximum current values of the N channel type field-effect transistor and the P channel type field-effect transistor is within a permissible range.
